(19) United States
(12) Patent Application Publication
(10) Pub. No.: US 2008/0054307 A1
(43) Pub. Date: Mar. 6, 2008

(54) Power supply wiring configuration in semiconductor integrated circuit

(76) Inventor: Tadahiro Shimizu, Kyoto (JP)

Correspondence Address: MCDERMOTT WILL & EMERY LLP, 600 13TH STREET, NW, WASHINGTON, DC, 20005-3096, US

(21) Appl. No.: 11/896,356

(22) Filed: Aug. 31, 2007

(30) Foreign Application Priority Data
Sep. 5, 2006 (JP) 2006-240010

(51) Int. Cl. H01L 27/105

(52) U.S. Cl. 257/207; 257/E27.081

(57) ABSTRACT

A first intermediate power supply wiring is arranged on an upper layer of a lowest power supply wiring arranged along a first direction. A second intermediate power supply wiring is arranged on an upper layer of the first power supply wiring. A third intermediate power supply wiring is arranged on an upper layer of the second intermediate power supply wiring. A highest power supply wiring is arranged along a second direction on an upper layer of the third intermediate power supply wiring. The first intermediate power supply wiring extends from an intersecting region of the highest power supply wiring and the lowest power supply wiring to an outer side of the intersecting region along the first direction. The second intermediate power supply wiring includes a wiring site extending from the intersecting region to the outer side of the intersecting region along the first direction and a wiring site extending from the intersecting region to the outer side of the intersecting region along the second direction. The third intermediate power supply wiring extends from the intersecting region to the outer side of the intersecting region along the second direction. The first intermediate power supply wiring is inter-layer connected to the lowest wiring layer. The second intermediate power supply wiring is inter-layer connected to the first intermediate power supply wiring and the third power supply wiring. The third intermediate power supply wiring is inter-layer connected to the highest wiring layer.

### BACKGROUND OF THE INVENTION

1. Field of the Invention

The present invention relates to a power supply wiring configuration in a semiconductor integrated circuit.

2. Description of the Related Art

Recently, higher integration of transistors on an LSI is advancing with miniaturization in manufacturing process and the lowering in power supply voltage is also advancing. The influence of voltage drop due to resistance of the power supply wiring in an LSI chip on the operation speed thus cannot be ignored. This becomes the cause of increase in delay time and malfunctioning in a logic circuit. Therefore, the design of the power supply wiring is very important. However, since the power supply wiring configuration is a configuration that occupies a large part in the wiring region, increase in the number of source wirings and widening in the width of the power supply wirings tend to decrease other wiring regions. This leads to increase in area of the integrated circuit.

In recent power supply wirings, a strap wiring configuration shown in FIG. 6 or the like is being adopted. In the strap wiring configuration, a lowest power supply wiring D1 of VDD and a lowest power supply wiring S1 of VSS connected to a function circuit are wired in a first direction X, and a highest power supply wiring D4 of VDD and a highest power supply wiring S4 of VSS are wired at constant intervals in a second direction Y perpendicular to the first direction X. In the strap wiring configuration, a supply path of the driving power is formed to the function circuit by connecting the lowest wiring layer to the highest wiring layer by way of a stacked via group G (collection of a plurality of via). The wiring region of each wiring layer other than the above is used for signal wirings, the lowest wiring layer and a second wiring layer have the first direction X as the preferential wiring direction, and a third wiring layer and the highest wiring layer have the second direction Y as the preferential wiring direction. In addition, a mesh power supply wiring configuration etc. in which the high power supply wiring such as the power supply wiring of the highest wiring layer is combined in multi-layers and in a mesh form has been employed conventionally.

Japanese Laid-Open Patent Publication (Japanese Laid-Open Patent Publication No. 2001-250917) discloses an integrated circuit device having a configuration in which

the supply path of the driving force is formed to the function circuit by connecting both power supply wirings by way of the stacked via in a region where the power supply wirings in the first direction of the low power supply layer and the power supply wirings in the second direction of the high power supply layer intersect; and

mutual wirings of a great number of function circuits are formed in an intermediate wiring layer; where

the formation of the wirings of the intermediate wiring layer is facilitated by periodically decimating the connecting configuration by the stacked via.

In the power supply configuration using the stacked via as described above, the wiring width of the low power supply wiring is generally smaller than the wiring width of the high power supply wiring. Thus, an intersecting region of the low power supply wiring and the high power supply wiring is assumed as a rectangle having the first direction X as the long side. The shape of the stacked via also becomes a rectangle (see heavy line of FIG. 6), and the wiring of the signal wiring R in the second direction Y shown with an arrow of chain double-dashed line in FIG. 6 becomes impossible in the intermediate wiring layer below the wiring region of the high power supply wiring. The wiring resource in the second direction of the intermediate wiring layer then reduces. Furthermore, the supply performance of the driving power lowers in the power supply configuration in which the stacked via is periodically decimated as in the Japanese Laid-Open Patent Publication described above.

### SUMMARY OF THE INVENTION

It is therefore a main object of the present invention to provide a power supply wiring configuration in a semiconductor integrated circuit that ensures the signal wiring in the second direction of the intermediate wiring layer without lowering the supply performance of the driving power to the function circuit.

A semiconductor integrated circuit of the present invention includes, a lowest power supply wiring arranged along a first direction; a first intermediate power supply wiring arranged on an upper layer of the lowest power supply wiring; a second intermediate power supply wiring arranged on an upper layer of the first intermediate power supply wiring; a third intermediate power supply wiring arranged on an upper layer of the second intermediate power supply wiring; and a highest power supply wiring arranged along a second direction on an upper layer of the third intermediate power supply wiring; wherein the second intermediate power supply wiring includes a wiring site extending from an intersecting region of the highest power supply wiring and the lowest power supply wiring to an outer side of the intersection region along the second direction; the third intermediate power supply wiring extends from the intersection region to the outer side of the intersection region along the second direction; the first intermediate power supply wiring is inter-layer connected to the lowest power supply wiring; the second intermediate power supply wiring is inter-layer connected to the first intermediate power supply wiring and the third intermediate power supply wiring; and the third intermediate power supply wiring is inter-layer connected to the highest power supply wiring.

Preferably, a lowest wiring layer including the lowest power supply wiring; a first intermediate wiring layer arranged on an upper layer of the lowest wiring layer and including the first intermediate power supply wiring; a second intermediate wiring layer arranged on an upper layer of the first intermediate wiring layer and including the second intermediate power supply wiring; a third intermediate wiring layer arranged on an upper layer of the second intermediate wiring layer and including the third intermediate power supply wiring; and a highest wiring layer arranged on an upper layer of the third intermediate wiring layer and including the highest power supply wiring are further arranged; wherein a region where signal wirings are arranged along the second direction is ensured in the first to the third intermediate wiring layers at the intersecting region.

In such configuration, the third intermediate power supply wiring extends along a longitudinal direction (second direction) of the highest power supply wiring. Thus, the third intermediate power supply wiring and the highest power supply wiring are inter-layer connected with a sufficient connecting area. The second intermediate power supply wring includes a wiring site extending along the extending direction (second direction) of the third intermediate power supply wiring and a wiring site extending along the extending direction (first direction) of the first intermediate power supply wiring. Thus, the connecting area at an inter-layer connecting region (connection region through via) between the second intermediate power supply wiring and the first intermediate power supply wiring also becomes sufficient. That is, the second intermediate power supply wiring includes a wiring site facing the third intermediate power supply wiring and a wiring site facing the first intermediate power supply wiring, and thus has a so-called cross shape. The lowest power supply wiring and the highest power supply wiring thus are inter-layer connected with a wide connecting area by arranging the second intermediate power supply wiring of such shape.

In a configuration in which a cross shaped wiring site is not formed in the second intermediate power supply wiring, it is difficult to ensure a wiring region at where the signal wirings are wired along the longitudinal direction (second direction) of the highest power supply wiring at an intersecting region of the highest power supply wiring and the lowest power supply wiring. In the configuration of the present invention in which the cross shaped wiring site is formed in the second intermediate power supply wiring, the signal wirings can be arranged along the longitudinal direction (second direction) of the highest power supply wiring at the intersecting region of the highest power supply wiring and the lowest power supply wiring. The wiring region of the signal wirings thus can be easily and sufficiently ensured.

Another semiconductor integrated circuit of the present invention includes a lowest power supply wiring arranged along a first direction; an intermediate power supply wiring arranged on an upper layer of the lowest power supply wiring; and a highest power supply wiring arranged along a second direction; wherein the lowest power supply wiring includes a branched power supply wiring branched from the lowest power supply wiring along the second direction; the intermediate power supply wiring has a shape facing the highest power supply wiring and the branched power supply wiring; and the intermediate power supply wiring is inter-layer connected to the highest power supply wiring and the branched power supply wiring.

Preferably, a lowest wiring layer including the lowest power supply wiring; an intermediate wiring layer arranged on an upper layer of the lowest wiring layer and including the intermediate power supply wiring; and a highest wiring layer arranged on an upper layer of the intermediate wiring layer and including the highest power supply wiring are further arranged; wherein a region where signal wirings are arranged along the second direction is ensured in the intermediate wiring layer at an intersecting region of the highest power supply wiring and the lowest power supply wiring.

Another configuration of the present invention described above is a configuration in which the second intermediate power supply wiring described above is arranged in the lowest power supply wiring as the branched power supply wiring. A connecting area is still sufficiently ensured in such power supply wiring configuration. Thus, there is no lack in the configuration for supplying the driving power, the circuit area does not need to be increased in excess, and greater amount of wiring resources in the second direction of the signal wirings in the intermediate wiring layer can be ensured.

According to another configuration of the present invention described above, the connecting area is sufficiently ensured, and thus there is no lack in terms of supplying the driving power, the circuit area does not need to be increased in excess, and greater amount of wiring resources in the second direction of the signal wirings in the intermediate wiring layer can be ensured.

In each configuration of the present invention, the first direction and the second direction may be of any direction, but are preferably orthogonal to each other in view of the configuration of the semiconductor integrated circuit. However, the first and the second directions may be substantially the same direction. In such configuration, the wiring direction of the highest power supply wiring and the wiring direction of the lowest power supply wiring become parallel, and thus the “intersecting region” mentioned above becomes an “overlapping region”. In this case as well, the connecting area is sufficiently ensured, and thus there is no lack in terms of supplying the driving power, the circuit area does not need to be increased in excess, and greater amount of wiring resources in the second direction of the signal wirings in the intermediate wiring layer can be ensured, similar to the above.

The first intermediate power supply wiring may be omitted, and the second intermediate power supply wiring may be inter-layer connected to the lowest power supply wiring. At least one of the first intermediate power supply wiring and the third intermediate power supply wiring is arranged in plurals and inter-layer connected to each other. A region where the inter-layer connection is carried out may include the intersecting region. An inter-layer connecting site of the second intermediate power supply wiring and the third intermediate power supply wiring, and an inter-layer connecting site of the third intermediate power supply wiring and the highest power supply wiring preferably have at least one part facing each other. The inter-layer connecting site is preferably formed of a plurality of via. The plurality of via is preferably arrayed along the first direction or the second direction.

The present invention includes an aspect in which one part of the lowest power supply wiring and the branched power supply wiring are power supply wirings of a standard cell.

An aspect in which the standard cell includes a transistor; and the branched power supply wiring configures a source of the transistor is also provided.

According to the inventions described above, the power supply wiring portion along the wiring direction of the lowest power supply wiring and the power supply wiring portion along the wiring direction of the highest power supply wiring are readily and reliably connected in the inter-layer connection from the lowest power supply wiring to the highest power supply wiring in the power supply wiring configuration of the semiconductor integrated circuit, and the following are obtained. That is, a greater amount of wiring resources in the second direction in the intermediate wiring layer are ensured while sufficiently ensuring the connecting area, suppressing increase in the circuit area, and without lowering the ability of the driving power supply.

The techniques of the present invention enable greater amount of wiring resources in the second direction to be ensured, and thus is applicable to various semiconductor integrated circuits.

### BRIEF DESCRIPTION OF THE DRAWINGS

Other objects of the invention will become apparent by understanding the embodiments described below, and will be defined in the attached Claims. A great number of benefits not mentioned in the specification should be apparent to those skilled in the art by implementing the invention.

FIG. 1 is a frame format plan view showing a power supply wiring configuration in a semiconductor integrated circuit according to a first embodiment of the present invention;

FIG. 2 is a frame format cubic diagram showing the power supply wiring configuration in the semiconductor integrated circuit according to the first embodiment of the present invention;

FIG. 3 is a frame format enlarged plan diagram showing the power supply wiring configuration in the semiconductor integrated circuit according to the first embodiment of the present invention;

FIG. 4 is a frame format plan view showing a power supply wiring configuration in a semiconductor integrated circuit in a variant of the first embodiment of the present invention;

FIG. 5 is a frame format plan view showing a power supply wiring configuration in a semiconductor integrated circuit according to a second embodiment of the present invention; and

FIG. 6 is a power supply wiring configuration view of a conventional semiconductor integrated circuit.

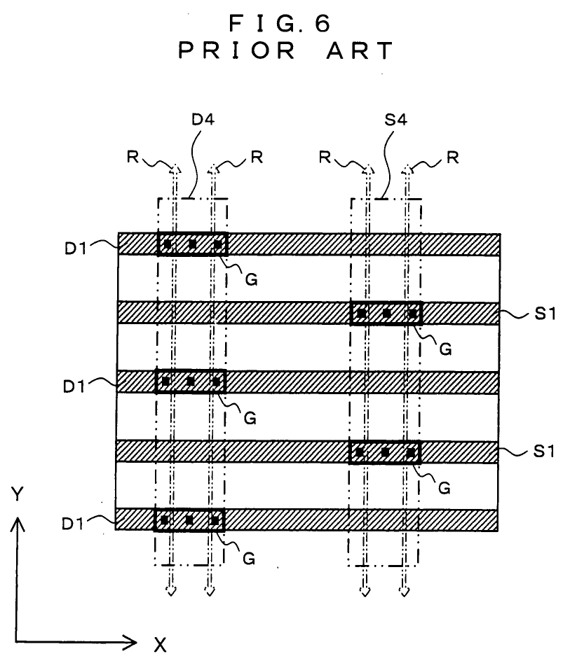

### DETAILED DESCRIPTION OF THE PREFERRED EMBODIMENTS

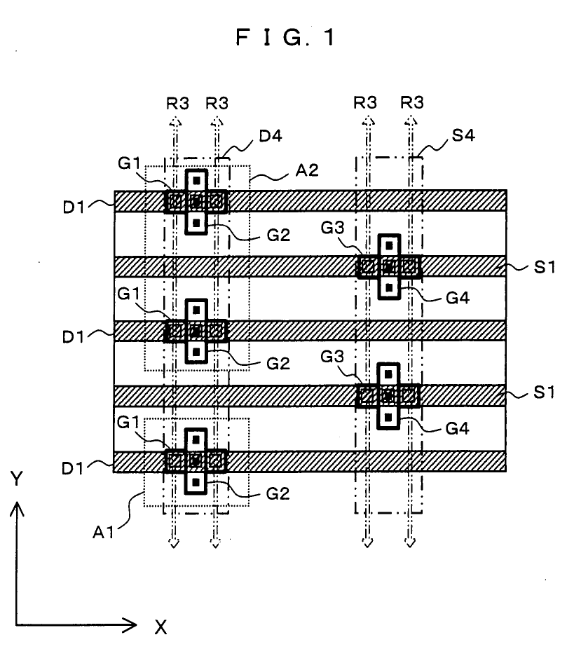

The embodiments of the present invention will now be described with reference to the drawings. FIG. 1 is a power supply wiring diagram of a semiconductor integrated circuit in each embodiment of the present invention. In the semiconductor integrated circuit, the wiring includes a lowest wiring layer, a highest wiring layer, a first intermediate wiring layer, a second intermediate wiring layer, and a third intermediate wiring layer. The first to the third intermediate wiring layers are arranged between the lowest wiring layer and the highest wiring layer, where the first intermediate wiring layer is arranged on the upper layer of the lowest wiring layer. The second intermediate wiring layer is arranged on the upper layer of the first intermediate wiring layer. The third intermediate wiring layer is arranged on the upper layer of the second intermediate wiring layer. The highest wiring layer is arranged on the upper layer of the third intermediate wiring layer. The first intermediate wiring layer and the third intermediate wiring layer are respectively configured by stacking one or a plurality of wiring layers. The second intermediate wiring layer is normally configured by a single wiring layer. The first intermediate wiring layer may be omitted. The first intermediate wiring layer is omitted in the first and the second embodiments described below.

### First Embodiment

In FIG. 1, D1 refers to a VDD power supply wiring (hereinafter referred to as lowest VDD power supply wiring) arranged in the lowest wiring layer, and S1 refers to a VSS power supply wiring (hereinafter referred to as lowest VSS power supply wiring) arranged in the lowest wiring layer. The lowest VDD power supply wiring D1 and the lowest VSS power supply wiring S1 are extended in a first direction X, and both power supply wirings D1, S1 are alternately wired at equal intervals in a second direction Y (orthogonal to the first direction). D4 refers to a VDD power supply wiring (hereinafter referred to as highest VDD power supply wiring) arranged in the highest wiring layer, and S4 refers to a VSS power supply wiring (hereinafter referred to as highest VSS power supply wiring) arranged in the highest wiring layer. The highest VDD power supply wiring D4 and the highest VSS power supply wiring S4 are extended in the second direction Y, and are alternately wired at equal intervals in the first direction X. This is called a strap wiring.

G1, G2, G3, and G4 are via groups. The via group G1 configures one part of an inter-layer connecting body for connecting the lowest VDD power supply wiring D1 and the highest VDD power supply wiring D4. The via group G1 is arranged in plurals. Each via group G1 is configured from three via arranged along the first direction X. The via group G1 connects the lowest wiring layer and the second intermediate wiring layer to each other.

Similar to the via group G1, the via group G2 configures one part of an inter-layer connecting body for connecting the lowest VDD power supply wiring D1 and the highest VDD power supply wiring D4. The via group G2 is arranged in plurals. Each via group G2 is configured from three via arranged along the second direction Y. The via group G2 connects the wiring layer groups across the second intermediate wiring layer, the third intermediate wiring layer, and the highest wiring layer.

The via group G3 configures one part of an inter-layer connecting body for connecting the lowest VSS power supply wiring D1 and the highest VSS power supply wiring S4. The via group G3 is arranged in plurals. Each via group G3 is configured from three via arranged along the first direction X. The via group G3 connects the lowest wiring layer and the second intermediate wiring layer to each other.

Similar to the via group G3, the via group G4 configures one part of an inter-layer connecting body for connecting the lowest VSS power supply wiring S1 and the highest VSS power supply wiring S4. The via group G4 is arranged in plurals. Each via group G4 is configured from three via arranged along the second direction Y. The via group G4 connects the second intermediate wiring layer, the third intermediate wiring layer, and the highest wiring layer to each other.

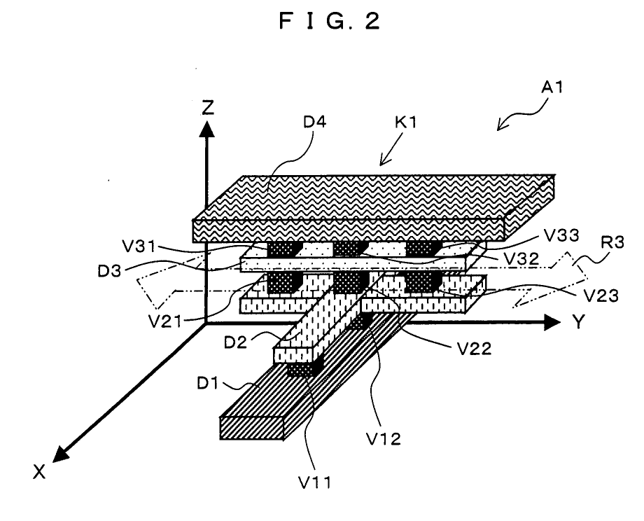

FIG. 2 is a view of an area A1 of FIG. 1 seen from diagonally above. An area in which other via of FIG. 1 is arranged has a configuration similar to FIG. 2. In the figure, z represents a height direction perpendicular to both the first direction X and the second direction Y. Furthermore, D2 shows a second VDD intermediate power supply wiring arranged in the second intermediate wiring layer. The second VDD intermediate power supply wiring D2 has a cross shape extending in the second direction Y and the first direction X. V11, V12 are via configuring the via group G1, and connect the lowest VDD power supply wiring D1 and the second VDD intermediate power supply wiring D2. The via V11, V12 are referred to as first via V11, V12. D3 indicates a VDD power supply wiring (hereinafter referred to as a third VDD intermediate power supply wiring) in the third intermediate wiring layer. V21, V22, and V23 show via for connecting the second VDD intermediate power supply wiring D2 and third VDD intermediate power supply wiring D3. The via V21, V22, V23 configure the via group G2. Via V31, V32, V33 are one part of the via group G2, and are a third via for connecting the third VDD intermediate power supply wiring D3 and the highest VDD power supply wiring D4. The first via V11 to V12, the second via V21 to V23, and third via V31 to V33 are each desirably arranged in numbers that satisfy IR drop and power supply electro migration resistance properties.

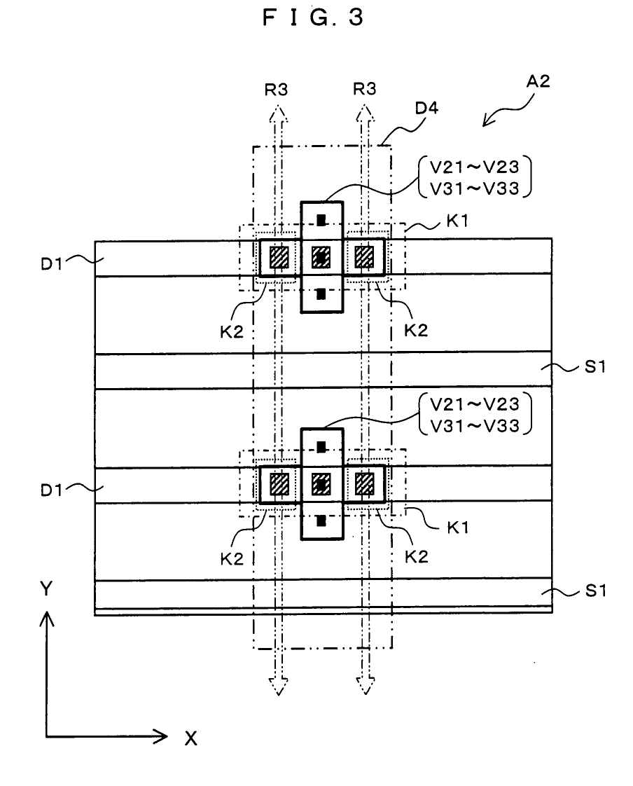

FIG. 3 is an enlarged view of an area A2 of FIG. 1. The second via V21 to V23 and the third via V31 to V33 respectively arrayed in the first direction X in the prior art are now arrayed in the second direction Y in the present embodiment, where a wiring region K2 in which a signal wiring R3 (see virtual arrow) of the intermediate wiring layer (third intermediate wiring layer) having the preferential wiring direction in the second direction Y can be wired can be ensured at an intersecting region K1 of the lowest power supply wiring D1 and the highest power supply wiring D4. The wiring region K2 is arranged in pairs on the left and the right. This is particularly effective when the wiring width of the highest power supply wiring D4 or the wiring width of the highest power supply wiring S4 is wide.

The effect of the present invention can be sufficiently expected even if the second via V22 at the center and the third via V32 at the center do not exist in the intersecting region K1. Similarly, the second via V21 and the third via V31, the second via V22 and the third via V32, as well as the second via V23 and the third via V33 overlapping in the up and down direction may not have an overlapping region, but the effect of the present invention still can be sufficiently expected.

The second intermediate power supply wiring D2 obviously does not need to have a cross shape and merely needs to have a shape capable of connecting the first via V11 to V12 and the second via V21 to V23, and may be a wide rectangular wiring in which a plurality of via can be arranged in both the first direction X and the second direction Y.

If the wiring region K2 in which the signal wiring R3 of the intermediate wiring layer (third intermediate wiring layer) having the preferential wiring direction in the second direction Y can be wired can be ensured at the intersecting region K1, the array of the second via V21 to V23 and the array of the third via V31 to V33 do not need to be in a line in the second direction Y and may be of any array. Furthermore, the configuration as in FIG. 2 may be used in areas where a great amount of signal wirings R3 are necessary in the second direction Y, and the conventional power supply configuration may be used in other areas.

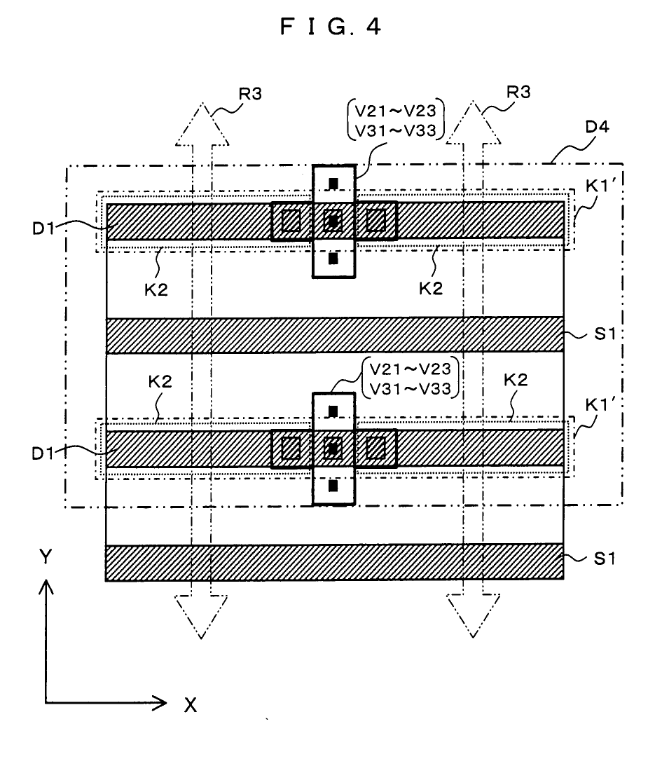

Even if the highest power supply wiring D4 is wired in the first direction X as in FIG. 4, the wiring region K2 in which the signal wiring R3 of the third intermediate wiring layer having the preferential wiring direction in the second direction Y can be wired can be ensured at an overlapping region K1′ of the lowest power supply wiring D1 and the highest power supply wiring D4 by having the configuration of the wiring layers below the highest wiring layer and the via similar to the above. Such wiring region K2 is in pairs on the left and the right. The number of third intermediate wiring layer may be increased.

### Second Embodiment

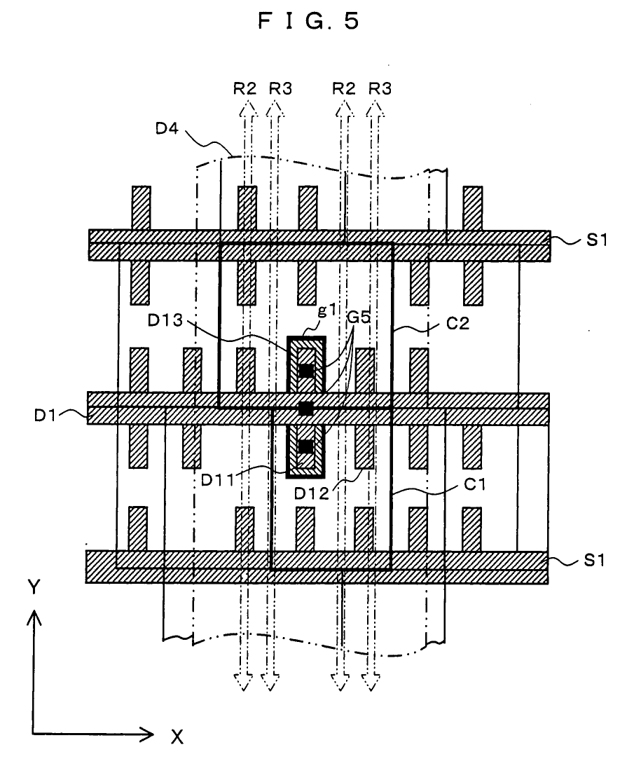

FIG. 5 is a power supply wiring diagram of a semiconductor integrated circuit according to a second embodiment of the present invention. The description of the region having the same configuration as the first embodiment will be omitted. In FIG. 5, C1 and C2 are standard cells including a transistor. A branched power supply wiring D11 and a branched power supply wiring D12 electrically connected in the same layer and at the same potential with the lowest power supply wiring D1 connected to a source of a P-channel transistor are wired in the second direction Y in the cell C1, and similarly, a branched power supply wiring D13 electrically connected in the same layer and at the same potential with the lowest power supply wiring D1 connected to a source of a P-channel transistor is also wired in the second direction in the cell C2. A power supply wiring group g1 is a power supply wiring configured by the second intermediate wiring layer and the third intermediate wiring layer, and is wired at the region where the branched power supply wirings D11, D13 are wired. A stacked via group G5 is arranged between each wiring layer from the lowest wiring layer to the highest wiring layer at the region overlapping the power supply wiring group g1, a stacked via configuration is formed by the first via, the second via, and the third via, and the lowest power supply wiring D1 and the highest power supply wiring D4 are electrically connected.

According to such power supply wiring configuration, the signal wiring R2 of the second intermediate wiring layer and the signal wiring R3 of the third intermediate wiring layer can be wired in the second direction Y in the region where the lowest power supply wiring D1 and the highest power supply wiring D4 overlap.

The effect of the present invention still can be sufficiently expected by using the first via, the second via, and the third via that do not have an overlapping region in place of the stacked via group G5. It should be apparent that the effect is similarly achieved for the wiring configuration of the VSS power supply wiring.

Obviously, the power supply configuration described above allows the signal wiring R2 of the second intermediate wiring layer to be wired in the second direction Y in a region where the lowest power supply wiring D1 and the highest power supply wiring D4 overlap even if the third intermediate wiring layer is removed, so as to be realized with the power supply configuration of all three layers, and furthermore, the number of intermediate wiring layers may be increased.

Moreover, if the branched power supply wirings D11, D12, and D13 are wired in the second direction Y in the same layer and at the same potential with the lowest power supply wiring D1, they do not necessarily need to be wirings connected to the source of the transistor.

Similar to the first embodiment, the via between each wiring layer is desirably arranged in numbers that satisfy IR drop as well as power supply electro migration resistance properties, and the relevant configuration may be used in regions where a great number of signal wirings are necessary in the second direction Y and the conventional power supply configuration may be used in other regions.

The signal wiring R2 of the second intermediate wiring layer and the signal wiring R3 of the third intermediate wiring layer can be wired in the second direction Y in a region where the lowest power supply wiring D1 and the highest power supply wiring D4 overlap by having the configurations below the highest wiring layer as described above even if the highest power supply wiring D4 is wired in the first direction X.

While the invention has been particularly shown and described with reference to preferred embodiments thereof, it should be understood that combination and arrangement of parts described in the preferred embodiments can be modified in various ways without departing from the spirit and the scope of the invention defined by the appended claims.

What is claimed is:

1. A semiconductor integrated circuit comprising:
a lowest power supply wiring arranged along a first direction;
a first intermediate power supply wiring arranged on an upper layer of the lowest power supply wiring;
a second intermediate power supply wiring arranged on an upper layer of the first intermediate power supply wiring;
a third intermediate power supply wiring arranged on an upper layer of the second intermediate power supply wiring; and
a highest power supply wiring arranged along a second direction on an upper layer of the third intermediate power supply wiring; wherein
the second intermediate power supply wiring includes a wiring site extending from an intersecting region of the highest power supply wiring and the lowest power supply wiring to an outer side of the intersection region along the second direction;
the third intermediate power supply wiring extends from the intersection region to the outer side of the intersection region along the second direction;
the first intermediate power supply wiring is inter-layer connected to the lowest power supply wiring;
the second intermediate power supply wiring is inter-layer connected to the first intermediate power supply wiring and the third intermediate power supply wiring; and
the third intermediate power supply wiring is inter-layer connected to the highest power supply wiring.

2. The semiconductor integrated circuit according to claim 1, further comprising:
a lowest wiring layer including the lowest power supply wiring;
a first intermediate wiring layer arranged on an upper layer of the lowest wiring layer and including the first intermediate power supply wiring;
a second intermediate wiring layer arranged on an upper layer of the first intermediate wiring layer and including the second intermediate power supply wiring;
a third intermediate wiring layer arranged on an upper layer of the second intermediate wiring layer and including the third intermediate power supply wiring; and
a highest wiring layer arranged on an upper layer of the third intermediate wiring layer and including the highest power supply wiring; wherein
a region where signal wirings are arranged along the second direction is ensured in the first to the third intermediate wiring layers at the intersecting region.

3. The semiconductor integrated circuit according to claim 1, wherein the first direction and the second direction are directions different from each other.

4. The semiconductor integrated circuit according to claim 1, wherein the first direction and the second direction are orthogonal to each other.

5. The semiconductor integrated circuit according to claim 1, wherein the first direction and the second direction are substantially the same direction.

6. The semiconductor integrated circuit according to claim 1, wherein
the first intermediate power supply wiring is omitted; and
the second intermediate power supply wiring is inter-layer connected to the lowest power supply wiring.

7. The semiconductor integrated circuit according to claim 1, wherein at least one of the first intermediate power supply wiring and the third intermediate power supply wiring is arranged in plurals and inter-layer connected to each other.

8. The semiconductor integrated circuit according to claim 1, wherein a site where the inter-layer connection is carried out includes the intersecting region.

9. The semiconductor integrated circuit according to claim 1, wherein an inter-layer connecting site of the second intermediate power supply wiring and the third intermediate power supply wiring, and an inter-layer connecting site of the third intermediate power supply wiring and the highest power supply wiring have at least one part facing each other.

10. The semiconductor integrated circuit according to claim 1, wherein the inter-layer connecting site is formed of a plurality of via.

11. The semiconductor integrated circuit according to claim 10, wherein the plurality of via is arrayed along the first direction or the second direction.

12. A semiconductor integrated circuit comprising:
a lowest power supply wiring arranged along a first direction;
an intermediate power supply wiring arranged on an upper layer of the lowest power supply wiring; and
a highest power supply wiring arranged along a second direction; wherein
the lowest power supply wiring includes a branched power supply wiring branched from the lowest power supply wiring along the second direction;
the intermediate power supply wiring has a shape facing the highest power supply wiring and the branched power supply wiring; and
the intermediate power supply wiring is inter-layer connected to the highest power supply wiring and the branched power supply wiring.

13. The semiconductor integrated circuit according to claim 12, further comprising:
a lowest wiring layer including the lowest power supply wiring;
an intermediate wiring layer arranged on an upper layer of the lowest wiring layer and including the intermediate power supply wiring; and
a highest wiring layer arranged on an upper layer of the intermediate wiring layer and including the highest power supply wiring; wherein
a region where signal wirings are arranged along the second direction is ensured in the intermediate wiring layer at an intersecting region of the highest power supply wiring and the lowest power supply wiring.

14. The semiconductor integrated circuit according to claim 12, wherein the first direction and the second direction are directions different from each other.

15. The semiconductor integrated circuit according to claim 12, wherein the first direction and the second direction are orthogonal to each other.

16. The semiconductor integrated circuit according to claim 12, wherein the first direction and the second direction are substantially the same direction.

17. The semiconductor integrated circuit according to claim 12, wherein an inter-layer connecting site of the lowest power supply wiring and the intermediate power supply wiring, and an inter-layer connecting site of the intermediate power supply wiring and the highest power supply wiring have at least one part facing each other.

18. The semiconductor integrated circuit according to claim 12, wherein the lowest power supply wiring and the branched power supply wiring are power supply wirings of a standard cell.

19. The semiconductor integrated circuit according to claim 18, wherein
the standard cell includes a transistor; and
the branched power supply wiring configures a source of the transistor.
